(19) United States
(12) Patent Application Publication
(10) Pub. No.: US 2007/0260097 A1
(43) Pub. Date: Nov. 8, 2007

(54) Deposition of Polymeric Materials and Precursors Therefor

(76) Inventor: John J. Senkevich, Rolla, MO (US)

Correspondence Address: HOVEY WILLIAMS LLP, 2405 GRAND BLVD., SUITE 400, KANSAS CITY, MO, 64108, US

(21) Appl. No.: 11/576,399

(22) PCT Filed: Mar. 15, 2006
(86) PCT No.: PCT/US06/09347

§ 371 Date: Mar. 30, 2007

Related U.S. Application Data
(60) Provisional application No. 60/662,977, filed on Mar. 18, 2005.
(60) Provisional application No. 60/665,922, filed on Mar. 28, 2005.
(60) Provisional application No. 60/709,844, filed on Sep. 21, 2005.

(51) Int. Cl. C23C 16/00

(52) U.S. Cl. 585/25; 427/487

(57) ABSTRACT

Substituted paracyclophanes are particularly useful as precursors in the formation of a cross-linkable polymer on a deposition substrate such as an electronic device being processed. The paracyclophane precursor including a cross-linkable substituent such as an alkynyl is cracked at the phenyl linkages. The substrate is subjected to the cracked precursor. As a result, an organic polymer is formed on the substrate. Cross-linking of the polymer through reaction, e.g. thermally induced reaction, of the cross-linkable substituents produces a thermally stable cross-linked polymer. The deposition of such cross-linked polymer is particularly useful for to sealing ultra low k dielectric materials used in the damascene process in the production of integrated circuits. Alternatively the polymer is also advantageous as an adhesive in wafer-to-wafer bonding. Alternatively, the polymer is useful as a hardmask to replace silicon nitride and silicon carbide in the back-end-of-the-line processing of electronic devices.

### CROSS REFERENCE

This application claims priority to U.S. provisional application 60/662,977 filed Mar. 18, 2005, U.S. provisional application 60/665,922 filed Mar. 28, 2005, and U.S. provisional application 60/709,844 filed Aug. 19, 2005 and Sep. 21, 2005 all of which with named inventor John J. Senkevich and all of which are hereby incorporated by reference in their entirety.

### FEDERALLY SPONSORED RESEARCH/DEVELOPMENT PROGRAM

This invention was made with Government support under contract DASG60-01-C-0047, awarded by the United States Army Space and Missile Defense Command. The Government has certain rights to the invention.

### TECHNICAL FIELD

This invention relates to chemical vapor deposition and in particular to chemical vapor deposition employing an organic precursor.

### BACKGROUND OF THE INVENTION

Chemical vapor deposition (CVD) is a process employed to form material regions on a substrate. Generally a deposition vapor is produced from a precursor or precursors by sublimation from solid precursors, evaporation from liquid precursor and/or direct use of gaseous precursors. To effect deposition, the combined deposition vapor is directed to a substrate that is typically maintained at an elevated temperature. Interaction between the deposition vapor and the substrate induces formation of a material region on the substrate. The resulting deposited material is either 1) modified chemically or physically by, for example, introducing energy, or 2) used as deposited.

A CVD process has a variety of advantages. Typically, material deposited on a substrate having topography forms conformally. That is, for the topography in FIG. 2 shown in cross-section as a groove 23 in substrate 21, a deposited region, 27, is conformal if the ratio of thickness 29 to thickness 28 is in the range 0.9 to 1.0. Additionally it is possible with certain precursor systems to achieve selective deposition on a portion of a composite substrate by a judicious choice of deposition conditions. In particular, deposition is selective if deposition occurs on a portion of a substrate surface having a first chemical composition but is essentially absent on a second portion having a second chemical composition.

Because of its many attributes, CVD processing is employed in a plethora of applications such as those involved in the manufacture of electronic devices. Exemplary of traditional CVD uses is the deposition of metals during integrated circuit manufacture. In recent years, many innovative applications for CVD processes have been proposed.

One such innovative approach stems from the emergence of the porous insulating materials necessitated by stricter design rules and use of multilevel interconnect structures in integrated circuits. As integrated circuit design rules have become more aggressive, the width and thickness of aluminum runners used to make electrical interconnections has decreased to the point that runner resistance is unacceptably large. Copper with its lower resistivity is an alluring substitute. However, conversion to copper is not achievable by simple substitution.

Aluminum runners are generally formed by depositing a blanket layer of aluminum. The mask is patterned so that portions of the aluminum layer to be removed are left exposed and portions that are to remain to form the electrical interconnections are covered. The exposed regions of the aluminum are then removed by an etching process such as reactive ion etching. The etching procedure and the resistance of the mask material to the etchant are tailored so that the exposed aluminum is removed without unacceptably degrading the mask.

Regrettably, copper is not susceptible to conventional etching procedures used in integrated circuit manufacture. To overcome this problem, the more complex damascene process is used to pattern copper. In a damascene process an insulating layer is formed and then etched to produce vias and trenches configured in the pattern desired for the copper interconnects. Copper readily diffuses through the insulating materials presently in use. Therefore to prevent such diffusion a barrier layer such as a tantalum nitride layer is typically conformally deposited by, for example, ionized physical vapor deposition (i-PVD) to cover the walls and bottom of the etched vias and trenches. Other materials, e.g. tantalum, and a copper seed layer are then sequentially deposited to expedite subsequent copper via and trench fill via electrodeposition. The region of copper overlying the insulator is removed by chemical-mechanical etching—a procedure that removes material by a combination of abrasive and wet chemical action.

As copper runners become thinner with stricter design rules the insulating layer is concomitantly thinned. To maintain the required insulating properties of this layer, material denominated low k insulators (k<3 with k defined as the ratio of the static permitivity of the material to the vacuum permitivity) have replaced the traditional silicon dioxide insulator. These low k materials are relatively porous. Even more significantly, the pores interconnect in ultra low k materials (materials with k˜2.5 such as carbon-doped silicates derived from silane precursors). Thus it is possible for gases and liquids used in processing to substantially penetrate these interconnected pores. Accordingly, coordination compounds or metallorganics used for barrier layer deposition, alkaline chemical baths alternatively employed for barrier layer deposition, slurry compositions used in material removal, wet chemical treatments associated with photolithography and/or even ambient moisture are all candidates for pore infusion (see Xie and Muscat, Proceedings of the Electrochemical Society, 2003 (26), 279 (2004)). As a result excessive permeation augmented by interlinked pores results in substantial degradation in the insulating properties of the low k material. Additionally, the fracture toughness of the ultra low k material is often severely impacted causing delamination from the barrier layer stack. Even without penetration of these agents the fracture toughness of the porous carbon doped silicates are already compromised.

The patterning of low k materials by reactive ion etching not only exposes its porous network at the sidewalls but also introduces roughness to the etch pit sidewall associated with the etching process. As discussed, a barrier layer is deposited on the sidewalls generally to a thickness, depending on the design rule, in the range 25 to 500 angstroms. The form of such thin, deposited material tends to emulate the surface character of the underlying substrate. Thus the rough sidewalls transfer through the barrier layer to produce a rough barrier layer that is not necessarily pinhole free. As a result the barrier layer loses its efficacy as a barrier between the low k dielectric and the copper. Additionally, a rough copper seed layer results, in turn, from deposition on a rough barrier layer ultimately affecting the grain pattern of the electroplated copper feature. The poor grain properties of the composition of the copper has an increased resistivity due to surface scattering that at least, in part, obviates the advantage of its use.

The sealing of the ultra low k material, especially the etched sidewalls, with a deposited material has been contemplated. However, finding suitable sealants that are formed by an acceptable technique has been an elusive goal. Realization of a viscoelastic polymer-based sealant that will improve the fracture toughness of a fragile porous carbon doped silicate and with an appropriate thermal stability (stability as measured by a thickness loss less than 2% up to 420° C.) remains particularly difficult to achieve.

Problems associated with the desire to increase integration or device complexity are not confined to those arising from the damascene structure of integrated circuits. Presently in most integrated circuits active devices such as transistors are formed in a single region of high quality single crystal silicon. Use of multiple active device levels to augment integration has been proposed but growth of such multiple levels of silicon with appropriate characteristics to support these devices is extremely difficult. To avoid the rigors of multilevel growth, device layers have been formed in a first silicon wafer and a second high quality silicon wafer is bonded to the first. The second wafer has a second level of device formed either before or after bonding. (See Lu et. al, 2003 IEEE International Interconnect Technology Conference (IITC), 74-76, San Francisco (June 2003)). It is possible to undertake processing with full wafers bonded to each other or die on wafer or die on chip. In each case a permanent dielectric adhesive facilitates bonding.

Similarly bonding of dissimilar wafers has the potential to enhance performance integration by joining, for example, logic devices on one wafer with memory, optical or microelectromechanical devices on a second wafer. Memory directly bonded on top of memory is another high performance design for 3-D technology. Bonding is generally expedited by an adhesive material between the two wafers. For the adhesive to function adequately, it should be a suitable insulator (dielectric constant in the range 1.5 to 4.0) and be stable at elevated temperatures, i.e. temperatures in the range 390 to 450 degrees C. One reported attempt to bond wafers involves use of benzylcyclobutane (BCB) deposited by placing a small portion of the liquid BCB on the wafer with subsequent spinning. The resulting adhesive layer exhibits limited thermal stability (decomposition at 350 degrees C.). Additionally, the spinning technique is not preferred because of the difficulties in maintaining uniformity of the resulting layer over 200 and 300 mm wafers as well as the potential for out gassing of residual solvent during subsequent thermal processing.

Thus many applications in a variety of situations are awaiting the development of new materials adaptable to convenient deposition techniques.

### SUMMARY OF THE INVENTION

Advantageous polymeric materials are depositable by chemical vapor deposition using substituted [2,2]paracyclophanes as precursors. In particular, the substituent is chosen so that cross-linking is inducible in the deposited material. Most significantly, the deposited polymeric materials are formed by a specific process where room temperature deposition is possible. Thus precursors having the chemical structure shown in FIG. 1 are vaporized such as by sublimation. The resulting vapor is cracked to break the linkage between the phenyl moieties and then directed to a substrate upon which a polymeric material is deposited. The deposited polymer in one embodiment is then cross-linked by introduction of energy, e.g. heat. Thus, for example, 4-ethynyl [2,2]paracyclophane is employed as a precursor for polymeric deposition. Subsequent cross-linking results from chemical reaction between and/or among the ethynyl moieties in the deposited polymer.

The deposited, cross-linked material has good electrical insulation, thermal, and mechanical properties, (dielectric constants of k less than 2.8, and a thermal stability up to at least 420 degrees C.). Additionally, by using appropriate CVD conditions selective deposition is achievable on ultra low k dielectric materials such as carbon-doped silicates relative to copper. Porous materials are also sealed by the deposited cross-linked material since it exhibits a low permeability to moisture, aqueous solutions, alcohols, and typical organic solvents.

Thus it is possible to deposit a polymeric cross-linkable material that has many attributes such as enhanced resistance to water penetration. The advantageous properties are further enhanced after cross-linking. The cross-linked polymer has the attributes required for a variety of applications such as bonding device substrates e.g. wafers to wafers, sealing of porous ultra low K dielectrics, and selective deposition allowing a variety of subsequent processing approaches.

### BRIEF DESCRIPTION OF THE DRAWINGS

FIG. 1 illustrates precursors involved in the invention; and

FIG. 2 is a cross-sectional view of a substrate involved with CVD deposition using precursors.

### DETAILED DESCRIPTION

The use of substituted [2,2]paracyclophanes as a precursor for the deposition of a cross-linkable polymer has a variety of uses. As discussed earlier, such uses include but are not limited to use for the sealing of porous low K materials employed in the damascene process, for an adhesive employable in the bonding of wafers and chips, for improving the mechanical stability of porous ultra low K dielectric materials and for selective deposition allowing subsequent processing such as deposition of cobalt tungsten phosphide. In the deposition process the substituted [2,2]paracyclophane is introduced into the vapor phase. The precursor is generally a solid at room temperature and so such introduction is typically produced by sublimation or melting with subsequent evaporation. The precursors typically at temperatures above 120 degrees C. produce an adequate flow rate of vapor for most operating conditions. The precise sublimation temperature to employ depends on the melting point of the precursor and is easily determined using a controlled sample. (In some cases the precursor melts before sublimation but still has an appreciable vapor pressure.) Generally a carrier gas, although not precluded, is not needed. Alternatively it is possible to dissolve substituted paracyclophane into a suitable solvent such as tetrahydrofuran and add the precursor to the deposition apparatus by direct liquid injection (DLI). (C. Xu and T. H. Baum, Materials Research Society Symposium Proceedings vol. 555 155-60 (1999)). Generally a carrier such as helium, argon, or nitrogen is used during DLI of these materials facilitates vacuum outgassing and improves deposition uniformity. Carrier gas flow rates in the range 5 to 500 sccm are used depending on the conductance and pumping speed of the CVD reaction and pumping stack respectively. If the substituted paracyclophane is a liquid, again DLI technology using the same carrier gases and conditions are employable.

The precursor in the vapor phase is then cracked to break the linkage between the phenyl moieties. Cracking is generally accomplished in a separate chamber having a base pressure in the range 1×10⁻⁷ Torr to 10.0 mTorr depending on the conductance and pumping speed of the CVD reactor and pumping stack respectively. The precursor is introduced into such pyrolysis chamber at a flow rate in the range 1 to 20 sccm and a precursor partial pressure in the range 0.1 to 10 mTorr. Cracking is affected by the introduction of energy such as heat energy. For the application of heat energy temperatures in the range 550 to 750 degrees C. are typically adequate for producing the desired bond cleavage.

The vapor flow after cracking is then directed to the deposition substrate. The substrate is advantageously held at room temperature but cooling to as low as −30 degrees C. or heating to temperatures as high as 200 degrees C. is not precluded. Generally, however, for a non-porous deposition substrate, temperatures above 100 degrees C. severely limit deposition thickness and typically temperatures of 50 degrees C. and below are preferred. Also, the lower the temperature, typically, the less conformal the deposition. The substrate is generally removed a distance in the range 20 to 100 cm from the region in which cracking is induced. This separation ensures that heat transfer from the cracking region to the substrate does not produce unacceptable deposition non-uniformity.

The base pressure in the deposition region is typically in the range 1×10⁻⁷ to 10.0 mTorr. A flow rate of cracked precursor in the range 1 to 20 sccm yielding a partial pressure in the range 0.2 to 10 mTorr is typically employed. Deposition times in the range 30 seconds to 60 minutes under such conditions generally produce deposited layer thicknesses in the range 12 to 20,000 angstroms. Thicknesses less than 12 angstroms tend to have pinholes and are unacceptable for applications such as sealing of pores. Deposited layer thicknesses greater than 20,000 angstroms tend to require uneconomic deposition times and material costs.

The deposited cross-linkable polymeric material cross-links by application of energy such as heat or ultraviolet light. Heat energy temperatures in the range 175 to 420 degrees C. applied for time periods in the range 1 min to 60 min results in cross-linking in deposited layers with thicknesses in the range 12 angstroms to 20,000 angstroms. Temperatures less than 175 degrees C. are typically ineffective in causing cross-linking while temperatures above 420 degrees C. cause degradation of the deposited layer. For use of ultraviolet light wavelengths in the range 185 nm to 248 nm at intensities in the range 0.01 to 5 W/cm² applied for times in the range 30 seconds to 10 min generally result in cross-linking. As previously discussed, cross-linking generally enhances the advantageous properties of the deposited cross-linkable polymer. However, the step of cross-linking the polymer adds time and expense to the process. Therefore, it is possible to balance the deposited polymer properties against time and expense through controlling the degree of cross-linking by concomitantly adjusting the time and temperature (or light intensity) employed for cross-linking. A control sample is easily used to determine appropriate conditions for a desired extent of cross-linking. The degree of cross-linking is monitored by observation of, for example, the triple bond or double bond stretch in the infrared spectrum of the polymer.

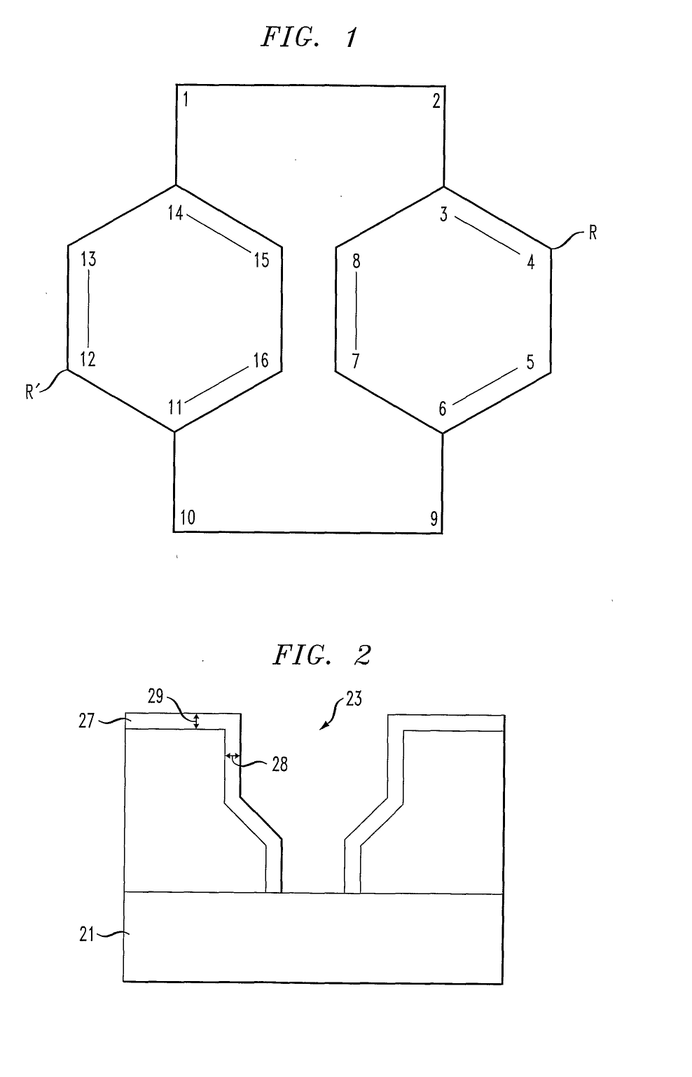

The precursor compounds of the invention are represented by the chemical structure of FIG. 1. Although the substituents as shown on the phenyl ring are shown at the positions indicated as 4 and 12. It is also acceptable for substituents to be bound to the ring at the other phenyl ring positions or for the precursor to be mono-substituted at, for example, at the 4 or at the 12 position. (The ring positions 4, 5, 7, 8, and 12, 13, 15, 16 are denominated benzyl ring positions, and it is also acceptable to have a cross-linkable moiety at these positions.) The number of cross-linkable substituents per precursor molecule is not critical but a precursor with one cross-linkable substituent per molecule is most easily synthesized. The substituents R and/or R′ wherever bound should be capable in the deposited polymer of reacting with other R moieties. In this manner R and/or R′ substituents bound to the deposited cross-linkable polymer are capable of undergoing reaction with another cross-linkable substituent.

It is particularly advantageous to employ cross-linkable substituents, R and/or R′ that include an ethynyl moiety. The linkages formed by cross-linking with the use of such entities result in carbon-carbon double bonds. It is contemplated that because of the stability of such bonds, the resulting materials have excellent thermal stability. Thus for applications such as wafer bonding and low k dielectric sealing use of such alkynyl substituents is preferred. Suitable alkynyls include those having moieties such as methyl, ethyl, isopropyl, t-butyl, phenyl and alkyls advantageously with 1 to 7 carbon atoms bound to an ethynyl group. (However, groups that present steric hindrance to cross-linking should be avoided.)

Other substituents that allow cross-linking are also useful. For example, use of an alkenyl containing entity also produces a cross-linkable polymeric material. However, the corresponding cross-linked polymer does not contain double bonds and therefore is somewhat less thermally stable. Again, an alkyl chain after the ethenyl moiety is also acceptable and generally should have from 1 to 6 carbon atoms. It is also possible to introduce the alkenyl substituent in a cyclic structure. Thus, for example, substituents such as cyclopentene are also useful. However, substituents such as fulvenyl, alkyl-substituted fulvenyl and cyclopentadiene tend to undergo Diels-Alder reactions with themselves (acting both as diene and dienophile). Use of such materials requires protecting the dieneophile with a material such as dimethyl acetylenedicarboxylate that is removable after introduction of the precursor into the gas phase or after deposition. Other cross-linkable materials such as substituents containing imine moieties are also useful. However, in general, nitrile substituents do not readily cross-link under thermal and ultraviolet light conditions and thus are not preferred.

The cross-linkable substituents need not necessarily be present at the 4 and/or 12 positions of the phenyl ring. Use of the 5,7,8,15,16 and 13 positions is also possible. Substitution at other carbon atoms (1,2,9 or 10) on the linkage between benzyl rings is not precluded. Very large or long substituted groups on the aryl position tend to yield polymers with poor thermo-mechanical properties. Cross-linkable n-alkyne substituents with more than 4 carbon atoms e.g. n-pentyne and groups occupying volumes greater than that of a phenyl acetylene group e.g. substituted phenylacetylene group are less desirable on the linkage positions. Substitution at phenyl or linkage carbons with substituents such as methyl and ethyl that do not cross-link in addition to at least one cross-linkable substituent is not precluded.

Precursors are synthesized generally by first brominating [2,2]paracyclophane as described by H. J. Reich and O. J. Cram, Journal of the American Chemical Society, 91, 3527 (1969) for the mono bromo compound and Y. L. Yeh and W. F. Gorham, The Journal of Organic Chemistry, 34, 2366 (1969) for the dibromo compound (both of which are hereby incorporated by reference in their entirety). The bromination process results in a mixture of brominated paracyclophanes and with further synthetic processing results in a corresponding mixture of precursors that are separable by standard techniques. The resulting brominated paracyclophane is reacted with a protected alkynyl or alkenyl moiety (such as trimethylsilane protected alkynyl or alkenyl) in the presence of an amine and palladium metal to form the protected alkynyl as described by Morisaki and Chujo, Polymer Preprints, 44(1), 980 (2003) which is hereby incorporated by reference in its entirety. The protecting group is then removed to form the desired precursor by treatment with n-butyl ammonium fluoride. The synthesis of bis ethynyl paracyclophane is reported in Boydston et. al. Angew. Chem. Int. Ed., 40(16), 2986 (2001) (which is hereby incorporated by reference in its entirety).

In another approach to synthesis, the acetyl substituted counterpart to the desired substituted paracyclophane is first prepared by Friedel-Crafts acylation. (See W. F. Gorham U.S. Pat. No. 3,117,168 Jan. 7, 1964 (which is hereby incorporated by reference in its entirety).) This acetyl counterpart is converted into the corresponding chlorovinyl substituted paracyclophane by reaction with phosphorus pentachloride in carbon tetrachloride. Then the alkynyl substituted material is produced by reaction with a strong base such as lithium diisopropyl amine (LDA). If the Cl—C═C—R″ substituent has a bulky R″ group such as a t-butyl group, the base employed to convert the chlorovinyl to the ethynyl moiety should be small. LDA is a very strong base and is effective for reducing the chlorovinyl to ethynyl (R″═H). However, for the case where R″-t-butyl, a smaller less bulky base should be used. For example, sodium amide or potassium hydroxide is suitable. The latter has a limited solubility so the reaction performed is in the solid-state (See P. D. Bartlett and L. J. Rosen, Journal of the American Chemical Society, 64, 543 (1942), which is hereby incorporated by reference in its entirety). Preparation of the paracyclophane with R″ being a phenyl is advantageously done using the procedure of W. F. Gorham U.S. Pat. No. 3,117,168, Jan. 7, 1964 for acylation with benzoyl chloride using [2,2]paracyclophane as a starting material. Once the phenyl acetyl group is placed on the [2,2]paracyclophane moiety, the vinyl chloride is produced as described and the ethynyl is created by using a small (non-sterically hindered) strong base such as sodium amide or potassium hydroxide.

In the embodiment of wafer bonding the wafers (or chips) to be bonded are generally capped with an oxide, e.g. silicon dioxide. This oxide surface is then advantageously treated with an adhesion promoter such as a silane adhesion promoter, e.g. methacryloxypropyltrimethoxysilane. (The use of epoxy and strained epoxy silanes such as 5,6-epoxyhexyltriethoxysilane and 2-(3,4-epoxycyclohexyl)ethyl-trimethylsilane is also possible.) A cross-linkable polymer as described previously is deposited on one or both of the wafer surfaces to be bonded. The two wafers are aligned such as optically for bonding as described, for example, in Lu et. al, 2003 IEEE International Interconnect Technology Conference (IITC), 74-76, San Francisco (June 2003). The wafers are then bonded using temperatures in the range 175 to 420 degrees C. and pressures in the range 1 to 20 atms. Temperatures below 175 generally lead to inadequate adhesion while temperatures above 420 degrees C. generally cause thermal instability. Pressures below 1 atm. although not precluded, lead to poor surface contact between the wafers while pressures above 20 atms are generally difficult to achieve over a 200 mm wafer surface.

Generally paracyclophanes having alkynyl substituents are employed for use in sealing porous materials such as low k dielectrics. Cracking is generally accomplished in the temperature range 550 to 750 degrees C. and deposition is generally accomplished using a substrate temperature of −30 degrees C. to 50 degrees C. with a vapor flow rate of 1 to 20 sccm and a total pressure in the range 0.1 to 10 mTorr.

The resulting deposited, cross-linkable polymer has a conformal configuration (a thickness ratio in the range 0.9 to 1.0) depending on the pressure of deposition. Higher pressures produce a less conformal deposition. The material also seals pores such as found in ultra low k dielectrics as measured by, for example, Rutherford Backscattering and Transmission Electron Microscopy. Pinhole free layers as thin as 12 angstroms are producible for a material that displays essentially no outgassing. (For a study of parylene N at a thickness of 50 angstroms see Senkevich, J. J., et al. Applied Physics Letters 84, 2617 (2004). Penetration into pores should be limited so that the desirable properties of the material being sealed are not unacceptably degraded. Cross-linking is induced using temperatures in the range 175 to 420 degrees C. or by using UV-light. Deposited materials after cross-linking also have thermal stability to temperatures as high as 420 degrees C. and exhibit viscoelastic properties that promote fracture toughness improvement for porous carbon doped silicates. Dielectric constants below 2.8 are typically obtained.

Selective deposition on low k dielectrics such as carbon doped silicates is achievable relative to copper using typical deposition conditions. The resulting selectivity between copper and dielectric material, e.g. ultra low K dielectric material, is particularly useful for many processing sequences. For example after copper runners are formed by a damascene procedure and planarized, a paracyclophane polymer is deposited and cross-linked. The selecting of this process allows deposition on the dielectric relative to the copper. Therefore the dielectric material surface is covered by cross-linked polymer but the copper runners are not.

Accordingly, in one embodiment the deposited cross-linked material improves the mechanical properties of the dielectric while leaving the copper unaffected and subsequent device layers are formed over the cross-linked polymer. In another embodiment the cross-linked polymer is used as a hard mask, for example, to replace silicon nitride or silicon carbide. In yet another embodiment building on the hard mask approach cobalt tungsten phosphide is deposited over the substrate having the selectivity deposited cross-linked polymer with exposed copper runners. (Deposition of cobalt tungsten phosphide is described in Hu et. al. Microelectronic Engineering, 70, 406 (2003), which is hereby incorporated by reference in its entirety). The deposited cobalt tungsten phosphide deposits selectively on the copper but not on the cross-linked polymer. Since cobalt tungsten phosphide does not form an acceptable layer in the presence of post-chemical-mechanical planarization exposed ultra low K dielectric, the intermediate cross-linked polymer functions as a hard mask and allows successful cobalt tungsten phosphide functioning as a barrier layer.

After sealing of the porous material or bonding of wafers, device fabrication is continued by using conventional techniques such as barrier deposition and copper metallization. The deposited and cross-linked polymeric materials have properties that are consistent with the use of such techniques and thus modification of presently employed device fabrication protocols is generally not required.

For applications involving other than electronic device fabrication, use of the deposited cross-linkable polymer without actual cross-linking is particularly advantageous if cost is critical and the most enhanced deposited region properties are not required. Although it has not been totally as yet resolved, it is believed the limited rotational freedom of cross-linkable substituents yields desirable properties such as low moisture permeability relative to non-cross-linkable substituents.

The following examples are illustrative of useful conditions relating to the invention.

### EXAMPLES

### Example 1

Approximately 130 mg of iron powder (average particle size of 10 μm) was mixed with 150 mL of chloroform and 130 mL of dichloromethane in a 1000 mL round bottom flask. The mixture was sonicated for 20 minutes using a commercial sonnicator and then an additional 250 mL of dichloromethane together with about 17.7 g of [2,2]paracyclophane was added. The entire mixture was left open to the atmosphere and stirred using a stirbar and stir plate for 2 hours. Gas chromatography of the crude reaction showed 87 percent yield of 4-bromo [2,2]paracyclophane.

The reaction mixture washed sequentially with two 150 mL aliquots of 10% (by weight) sodium bisulfate aqueous solution, a 150 mL aliquot of 1 M aqueous NaOH, and 150 mL of saturated NaCl aqueous solution. After washing, the mixture was dried over anhydrous MgSO₄. The remaining solvent was evaporated using a rotovap at a temperature of 40 degrees C. The residue was recrystallized from hot (50 degrees C.) chloroform. Recrystallization did not substantially affect the purity of the product.

### Example 2

Immediately before use 1,4 dioxane was distilled under a nitrogen blanket using a reflux condenser over an excess of sodium metal and benzophenone ketyl. Cesium carbonate was dried in a nitrogen atmosphere at 115 degrees C. for 12 hours. Ethynyl-triethylsilane, tris(dibenzylideneacetone)dipalladium(0), and tri-t-butyl phosphine were used as received from commercial sources.

Reaction compositions were prepared in 1.5 mL crimp-top vials each with a small magnetic stir bar. There was delivered to each vial approximately 0.05 mmol of the 4-bromo[2,2]paracyclophane prepared and purified as described in Example 1, 0.15 mmol CsCO₃, 0.08 mmol ethynyl-triethylsilane, 0.33 mL of an 0.0022N solution of tris(dibenzylideneacetone) dipalladium (0) in the distilled dioxane, 0.33 mL of a 0.188M tri-t-butylphosphine in the distilled 1,4dioxane, and 0.33 mL of a 0.137M solution of tri-t-butyl phosphine in the distilled 1,4dioxane. The samples were heated for 3 hours at 95 degrees C. while stirring with the magnetic stir bars. After separation and washing, the product was subjected to gas-chromatography using a syringe and showed a 97% conversion to 4-triethylsilaneethynyl[2,2]paracyclophane.

### Example 3

A solution of 5.0 mmol of the 4-(ethylsilaneethynyl)[2,2]paracyclophane (prepared and purified as described in Example 2) in 0.50 mL of tetrahydrofuran (HPLC grade) was prepared. To this solution was added 10.0 mL of a 1.0 M solution of Bu₄ⁿNF in tetrahydrofuran. The unheated reaction mixture was stirred by a magnetic stirbar in a nitrogen atmosphere approximately 16 hours. The tetrahydrofuran was evaporated off using a rotovap. The residue was 90% by weight of 4-ethynyl[2,2]paracyclophane as measured by gas-chromatography.

### Example 4

### Preparation of 4-Acetyl[2,2]paracyclophane,

Into a 5 L round bottomed flask, cooled to −78 degrees C. and under a nitrogen atmosphere were placed [2/2]paracyclophane (225 g, 1080 mmol) and anhydrous methylene chloride (1 L). To the well-stirred suspension was added, by cannula over 40 mins, a solution of AlCl₃ (254.25 g, 1907 mmol, 1.77 equiv), in methylene chloride (1 L); care was taken to ensure the internal temperature never rose above −50 degrees C. After the addition was complete the orange mixture was stirred in the cold bath for an additional hour, then was removed from the cold bath, and warned slowly to −20 degrees C. (approximately 40 mins). The mixture was carefully poured into 2 L of ice-cold water, stirred for 20 mins and then the upper aqueous layer removed by decantation. The organic mixture washed with water (2×1 L), dried (MgSO₄), then concentrated under reduced pressure to an oily yellow solid. The solid was pre-purified by suspending it in hexanes/CH₂Cl₂ (1:1) and passing it through 200 g of silica gel with the same solvent system being used to elute the sample. The semi-pure material (˜85%, ¹H NMR) was passed through a second silica plug (400 g silica) and eluted with hexanes/CH₂Cl₂ (3:1) to give a clean sample of 4-acetyl[2,2]paracyclophane as an off-white solid (186 g, 69%). Use of 100 g of 2 (480 mmol) gave 82 g of 3 as white powder (82 g, 68%).

### Example 5

### Preparation of 4-(1-Chlorovinyl)[2,2]paracyclophane,

To a stirred suspension of 4-acetyl[2,2]paracyclophane from Example 1 (82 g, 328 mmol) in dry CCl₄ (420 mL) and under a nitrogen atmosphere was added PCl₅ (83 g 399 mmol, 1.22 equiv.). The mixture was refluxed for 2 h, over which time all the material dissolved. The mixture was cooled to room temperature and then poured slowly into ice-cold water (2 L). The upper aqueous layer was decanted off and the milky white organic layer washed (water, 3×1 L). Then most of the solvent was removed under reduced pressure. The mixture was passed through a pad of silica gel (200 g, CH₂Cl₂ elution), and the filtrate dried (MgSO₄) then concentrated under reduced pressure to give a sample of 4-(1-chlorovinyl)[2,2]paracyclophane that was contaminated to an extent of approximately 15% (¹H NMR). A second plug (200 g silica, hexanes/CH₂Cl₂ 1:1 elution), gave a sample of 4-(1-chlorovinyl)[2,2]paracyclophane that was approximately 95% pure. A third plug (200 g silica, hexanes/CH₂Cl₂ 3:1 elution), gave an analytical sample of 4-(1-chlorovinyl)[2,2]paracyclophane as a white solid (69 g 77%).

The sample was left in the dark at ambient temperature for 10 days and over this time darkened considerably and a green-brown residue was left in the flask. The material was passed through a pad of 200 g silica and eluted with hexane and CH₂CL₂ 1:1 to give a clean sample of 4-(1-chlorovinyl)[2,2]paracyclophane (63 g 72%. Storage in a freezer for timely use is preferred.) Use of 186 g of 4-acetyl[2,2]paracyclophane (186 mmol) with CCl₄ that was not stored/packed under inert atmosphere gave 127 g of 4-(1-chlorovinyl)[2,2]paracyclophane (64%) that was 85% pure by ¹H NMR spectroscopy.

### Example 6

### Preparation of 4-(Ethynyl)[2,2]paracyclophane,

Into a 2 L round-bottomed flask cooled to −78 degrees C. and under a nitrogen atmosphere were placed 4-(1-chlorovinyl)[2,2]paracyclophane (63 g 233.5 mmol) and anhydrous tetrahydrofuran (THF) (710 mL). To this solution was added LDA (385 mL, 1.8 M, 693 mmol, 2.97 equiv.) over a 20 min period. After the addition was complete the now dark brown solution was stirred at this temperature for an additional 1.5 h, then removed from the cold bath, and allowed to warm slowly to 0 degrees C. (approximately 1 h). To the mixture was added water (100 mL) and then ether (150 mL). The organic layer was collected, washed (water, 2×400 mL), dried (MgSO₄), and then concentrated under reduced pressure to an oily yellow solid. The solid was pre-purified by suspending it in hexane/CH₂Cl₂ (1:1) and passing it through 250 g of silica gel with the same solvent system being used to elute the sample. The semi-pure material (approximately 85%, ¹H NMR) was passed through a second silica plug (250 g silica) and eluted with hexanes/CH₂Cl₂ (3:1) to give a clean sample of 4-ethynyl[2,2]paracyclophane as an off-white solid (41.8 g, 75%) that was greater than 98% pure by gas chromatography-mass spectrometry. Use of 127 g of approximately 85% pure 4-(1-chlorovinyl)[2,2]paracyclophane gave 4-ethynyl[2,2]paracyclophane.

### Example 7

### Synthesis of 4-Acetyl tosylhydrazone [2,2]paracyclophane

Approximately 2.06 g of 4-acetyl [2,2]paracyclophane (described in Example 4), 1.78 g of tosylhydrazide, 15 mL of ethanol and 1 drop of concentrated HCl was added to a 50 mL round bottom flask and mixed. The round bottom flask was heated to 70 degrees C. under a nitrogen purge with a micro reflux condenser. After 3 hours the solution was allowed to cool to room temperature. The mixture was transferred to an Erlenmeyer flask and re-crystallized in ethanol.

### Example 8

### Synthesis of 4-Vinyl [2,2]paracyclophane

Approximately 2.75 g of 4-acetyl tosylhydrazone [2,2]paracyclophane from Example 7 was added to an oven dried flask, purged with dry nitrogen, and then 30 mL of anhydrous THF was added to the 100 mL 3 neck round bottom flask. The flask was cooled to −90° C. with a liquid nitrogen/acetone bath. The reagent n-butyl lithium (1.6 M in hexanes) was added dropwise with a syringe until a sustained color was obtained, (total volume 16 mL). A bright red solution was created. The reagent n-butyl lithium was added in 4 mL aliquots with a syringe. The solution was allowed to warm to room temperature. As it warmed it turned from red to brown in color. At room temperature it turned from brown to green. Approximately 25 mL of dionized H₂O was added and the color turned yellow. The phases were separated and the aqueous phase was extracted with 2×15 mL portions of diethylether. The combined organics were washed with 10 mL dionized H₂O, 2×15 mL portions of saturated NaCl and dried with anhydrous MgSO₄. The organic phase was then filtered and rotary evaporated to 80 degrees C. in vacuo. The liquid residue was placed in the vacuum oven at 55 degrees C. overnight. The product was vacuum distilled on a short path column at 250 mTorr using an oil bath heated to 190 degrees C. By gas chromatography-mass spectrometry, 4-vinyl [2,2]paracyclophane was made with a volatile impurity of m/e=220 g/mol.

### Example 9

Poly(ethynyl-p-xylyene) was deposited on a silicon substrate. This deposition was accomplished using 4-ethynyl[2,2]paracyclophane (EPC) as a precursor. Approximately 1.0 g of EPC was placed in a Pyrex sublimation chamber with a stainless steel vacuum flange having dimensions of 1 inch×6 inches. This chamber was evacuated to a base pressure of less than 10 mTorr using a conventional roughing pump. A liquid nitrogen trap attached to the chamber above the rough pump was employed to prevent vapors from infiltrating the pump. The sublimation chamber was connected through a valve to a pyrolysis chamber made of Inconel with the dimensions of 1.5 inches×12 inches. The pyrolysis chamber was also evacuated to a base pressure of less than 10 mTorr and was heated to 680 degrees C. using a resistive heated furnace. The pyrolysis chamber was connected to a deposition chamber by a stainless steel vacuum flange. This connection region was heated with a heating tape to about 145 degrees C. to prevent deposition of the polymer on the walls of this region. For the same reason the region connecting the sublimation and pyrolysis chamber was heated to 135 degrees C. using a heating tape to prevent the condensation of the precursor.

While being evacuated the sublimer was heated to 114 degrees C. When the temperature had stabilized for about one minute, the valve between the sublimation chamber and pyrolysis chamber was shut. The deposition chamber made of stainless steel and having a diameter of 4 inches connected to the pyrolysis chamber was brought to atmospheric pressure. A three inch un-patterned silicon wafer with major face in the <100> crystallographic plane that was used as received was placed on a large (approximately 3 mm) mesh sample holder in the deposition chamber and the deposition chamber evacuated to less than 10 mTorr. The value between the pyrolysis chamber and sublimation chamber was opened causing the pressure measured at the backside of the wafer by a 250 degrees C. capacitance manometer to rise approximately 1.1 to 2.0 mTorr over the base pressure.

After about 20 minutes, a 180 nm thin film was deposited on the silicon wafer. The polymer deposition rate was about 9 nm/min. The resulting film showed infrared absorption at 3290 cm⁻¹ indicative of ethynyl groups. Deposition was discontinued by closing the valve between the sublimation and pyrolysis chamber. The deposition chamber was vented and the silicon wafer removed.

### Example 10

The film deposited in Example 7 was cross-linked. This cross-linking was accomplished by placing the silicon wafer with deposited film in a vacuum anneal furnace. The furnace was evacuated to a base pressure of about 7.5 mTorr with a rough pump. The furnace was purged for 5 minutes with a 200 mTorr purge of argon gas. After the purge the film was annealed for 30 minutes at 380 degrees C. Annealing was terminated by turning off the furnace and allowing it to cool to about 100 degrees C., the furnace vented, and the wafer removed.

There was no observed infrared absorption peak at 3290 cm⁻¹ and this peak absence was indicative of substantial cross-linking. (A similar wafer annealed at 250 degrees C. for 30 minutes showed only partial diminution of the 3290 cm⁻¹ peak.) The deposited cross-linked film had dielectric constant of 2.8, a leakage current of 0.8×10⁻⁹ A/cm² at 1 MV/cm and breakdown characteristics of 3.0 MV/cm.

1. A process for fabricating an article comprising the steps of formation of a polymer on a substrate and progression towards completion of said article wherein said formation comprises 1) establishing a precursor gas flow, wherein said precursor comprises a substituted paracyclophane having a cross-linkable moiety, 2) cracking said precursor by cleaving carbon bond linkages between phenyl moieties to form a cracked precursor, 3) contacting said substrate with said cracked precursor and, 4) providing energy to induce cross-linking through reaction of at least a portion of said cross-linkable moieties.

2. The process of claim 1 wherein said cross-linkable moiety comprises an alkynyl.

3. The process of claim 2 wherein said cross-linkable moiety comprises an ethynyl moiety bonded to said phenyl moiety of said precursor.

4. The process of claim 1 wherein said cross-linkable moiety comprises an alkenyl.

5. The process of claim 1 wherein said article comprises a device.

6. The process of claim 5 wherein said device comprises an electronic device.

7. The process of claim 6 wherein said substrate includes a region with pores and said polymer seals said pores.

8. The process of claim 7 wherein said region comprises an ultra low K electrical insulator.

9. The process of claim 7 wherein said substrate during said contacting of said substrate by said cracked precursor is maintained at a temperature in the range −30 to 200 degrees C.

10. The process of claim 9 wherein said cracking is done by subjecting the precursor gas flow to a temperature in the range 500 to 850 degrees C.

11. The process of claim 1 wherein said substrate during said contacting of said substrate by said cracked precursor is maintained at a temperature in the range −30 to 100 degrees C.

12. The process of claim 1 wherein said cracking is done by subjecting the precursor gas flow to a temperature in the range 500 to 850 degrees.

13. The process of claim 1 wherein said progression towards completing said devices comprises adhering a second substrate to said substrate using said polymer as an adhesive to produce said adhering.

14. The process of claim 1 wherein said gas flow is produced by sublimation.

15. The process of claim 1 wherein said substrate comprises a porous material.

16. The process of claim 1 wherein said substrate has an exposed surface comprising a region of copper and a region of dielectric material whereby deposition selectively occurs on said region of dielectric.

17. The process of claim 16 wherein said progression towards completion comprises depositing cobalt tungsten phosphide on said substrate after said cross-linking.

18. The process of claim 1 wherein said substrate has an un-patterned deposition surface comprising a porous dielectric material and said formation of said cross-linked polymer occurs on said porous dielectric material.

19. A process for fabricating an article comprising the formation of a polymer on a substrate wherein said formation comprises 1) establishing a precursor gas flow wherein said precursor comprises a substituted paracyclophane having a cross-linkable moiety, 2) cracking said precursor by cleaving carbon bond linkages between phenyl moieties to form a cracked precursor, and 3) contacting said substrate with said cracked precursor.

20. The process of claim 19 wherein said cross-linkable moiety comprises an alkynyl.

21. The process of claim 20 wherein said cross-linkable moiety comprises an ethynyl moiety bound to said phenyl moiety of said precursor.

22. The process of claim 19 wherein said cross-linkable moiety comprises an alkenyl.

23. The process of claim 19 wherein said cracking is done by subjecting said precursor gas flow to a temperature in the range 500 to 850 degrees C.

24. A [2,2]paracyclophane having a substituent on a benzyl ring position, wherein said substituent comprises —C═C—R′ and —C═C—R′ and wherein R′ is chosen from the group consisting of methyl, ethyl, isopropyl and t-butyl.
